(19) United States
(12) Patent Application Publication
(10) Pub. No.: US 2003/0063701 A1
(43) Pub. Date: Apr. 3, 2003

(54) Method and apparatus for minimizing jitter and wander in a clock source

(76) Inventor: John M. Eubanks, Joliet, IL (US)

Correspondence Address: Lawrence M. Cho, Tellabs Operations, Inc., 1415 West Diehl Road, MS 16, Naperville, IL, 60563, US

(21) Appl. No.: 10/226,440

(22) Filed: Aug. 23, 2002

Related U.S. Application Data
(60) Provisional application No. 60/316,625, filed on Aug. 30, 2001.

(51) Int. Cl. H03D 3/24

(52) U.S. Cl. 375/376

(57) ABSTRACT

A clocking system is disclosed. The clocking system includes a digital phase-locked loop having a numerically controlled oscillator that generates a clock. The clocking system also includes an analog phase-locked loop, coupled to the digital phase-locked loop, that filters out jitter from the clock to allow the clock to be used as a system clock.

### RELATED APPLICATIONS

This application claims the benefit of the priority date of U.S. Provisional Application No. 60/316,625 filed on Aug. 30, 2001 under 35 U.S.C. §19(e).

### FIELD OF THE INVENTION

The present invention relates to the field of digital communications. More specifically, the present invention relates to the application of digital phase-locked loops for frequency synthesis, clock and data recovery, and jitter/wander filtering.

### BACKGROUND

The importance of system synchronization in telecommunication networks has increased dramatically with the introduction of Synchronous Optical Network (SONET) and Synchronous Digital Hierarchy (SDH). Synchronization allows digital equipment in a communication network to operate at the same average frame rate. This prevents slips that result in the momentary loss or repetition of data.

One of the requirements of a SONET network element is that it fit within the synchronization hierarchy as described in GR-253 and GR-1244. Digital cross-connects typically use stratum 3e clocks that provide the network element with the ability to filter wander from its incoming timing source and reduce the amplitude of wander on the outgoing optical facilities. The local clock requires an extremely low bandwidth (e.g. 0.001 Hz) to provide this filtering function. Typically, a digital phase-locked loop (DPLL) is used to provide the low bandwidth. However, the raw clocks generated by DPLLs are inherently jittered because of the discrete nature of the DPLL output.

One approach used in the past to address the jitter in the raw clock generated by DPLLs is the utilization of a digitally controlled oscillator (DCO) in conjunction with an Analog Phase-Locked Loop (APLL). DCOs typically use either dual- or tri-modulus counters to generate the DPLL output clock. The modulus of the counter is dithered to match the average frequency of the incoming timing source. This dithering, however, requires continuous software intervention even when holding the output frequency steady. Peak-to-peak jitter on the output of the DPLL is large and must be filtered by an analog phase locked loop (APLL). There are several drawbacks associated with using DCOs. First, DCOs require a high level of processor utilization. Second, DCOs require complex dithering algorithm to produce desired output frequencies with high-frequency jitter that can be filtered by the APLL. Thirdly, large external components are required to implement the low-bandwidth APLL used by DCOs.

A second approach used in the past to address the jitter in raw clocks generated by DPLLs is the utilization of direct digital synthesis (DDS). A phase accumulator is used to address a sine/cosine lookup table. The values in the lookup table control a digital to analog converter (DAC) that generates an analog sine wave. The sine wave must then be filtered with a low-pass filter and connected to a comparator to generate the output clock. The DDS approach however requires specialized circuitry that includes a DDS synthesizer, DAC, low-pass filter, and a comparator. These specialized circuitry can be costly and complex, and the additional componentry decreases the products reliability.

Thus, what is needed is a method and apparatus for minimizing jitter and wander in a clock source.

### SUMMARY

A clocking system is disclosed according to an embodiment of the present invention. The clock system includes a digital phase-locked loop (DPLL) having a numerically controlled oscillator (NCO) that generates a clock. The clocking system also includes an analog phase-locked loop (APLL), coupled to the DPLL. The APLL filters out jitter from the clock to allow the clock to be used as a system clock.

A method for managing a clocking system is disclosed according to an embodiment of the present invention. A phase detector reference frequency is determined. A DPLL clock frequency and NCO accumulator width is determined. DPLL jitter frequencies are determined. A phase increment register width is determined.

A method for generating a system clock is disclosed according to an embodiment of the present invention. A most significant bit from a phase accumulator register of a NCO is used as a clock.

### BRIEF DESCRIPTION OF THE DRAWINGS

The features and advantages of the present invention are illustrated by way of example and are by no means intended to limit the scope of the present invention to the particular embodiments shown, and in which:

FIG. 1 is a block diagram of a clocking system according to an embodiment of the present invention;

FIG. 2 is a block diagram of a digital phase locked loop (DPLL) as shown in FIG. 1;

FIG. 3 is a block diagram of a phase detector as shown in FIG. 2;

FIG. 4 is a block diagram of a numerically controlled oscillator (NCO) as shown in FIG. 2;

FIG. 5 illustrates the NCO output clock frequency as a function of phase increment and DPLL clock frequency;

FIG. 6 illustrates NCO output clock period dithering;

FIG. 7a illustrates NCO jitter frequency as a function of divide ratio;

FIGS. 7b-e illustrates residual NCO jitter frequencies with the NCO jitter frequency plotted against divide ratios;

FIG. 8 is a block diagram of an analog phase locked loop (APLL) as shown in FIG. 1;

FIG. 9 illustrates APLL clock edge when APLL bandwidth is much less than the DPLL jitter frequency;

FIG. 10 illustrates APLL clock edge when APLL bandwidth is much greater than the DPLL jitter frequency;

FIG. 11 is a flow chart illustrating a method for designing a clocking system according to an embodiment of the present invention;

FIG. 12 illustrates DPLL jitter frequency as a function of divide ratio;

FIG. 13 illustrates a DPLL phase detector circuit according to an embodiment of the present invention;

FIG. 14 illustrates a phase error counter and register according to an embodiment of the present invention;

FIG. 15 is a block diagram illustrating a loop filter according to an embodiment of the present invention; and

FIG. 16 illustrates an APLL phase detector according to an embodiment of the present invention.

### DETAILED DESCRIPTION

A method and apparatus for minimizing jitter and wander in a clock source is described. In the following description, numerous specific details are set forth in order to provide a thorough understanding of the present invention. It should be appreciated that the invention may be practiced without these specific details. In other instances, well-known equipment, components and techniques have not been described in particular detail in order to avoid unnecessarily obscuring the present invention.

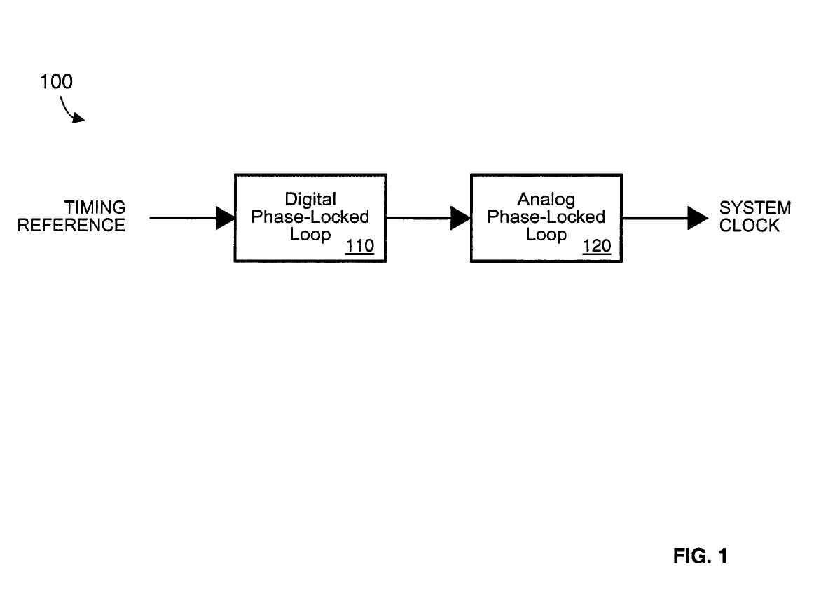

FIG. 1 is a block diagram illustrating clocking system 100 according to an embodiment of the present invention. The clocking system 100 includes a digital phase-locked loop (DPLL) 110. The DPLL is coupled to an analog phase-locked loop (APLL) 120. According to one embodiment, the DPLL 110 includes a numerically controlled oscillator (NCO) (not shown) that produces an output clock that is locked to an input signal. The input signal may be, for example, a timing reference. The NCO may have a very fine granularity that generates an output clock having a frequency that can very closely match the frequency of the input signal. This provides a simple holdover control that does not require software intervention which is normally the case in the digitally-controlled oscillator (DCO) approach.

According to an embodiment, the DPLL 110 has a jitter transfer bandwidth of 0.001 Hz that meets stratum 2 and 3E filtering characteristics. The phase dithering frequency of the NCO may be controlled such that the jitter may be filtered by the following the APLL 120. Thus the APLL 120 may be used to synthesize the frequency of the system clock and filter the jitter from the DPLL 110. This allows the clocking system 100 to operate without a sine/cosine lookup table, a digital to analog converter (DAC), a low-pass filter, and a comparator which are normally present in the direct digital synthesis (DDS) approach.

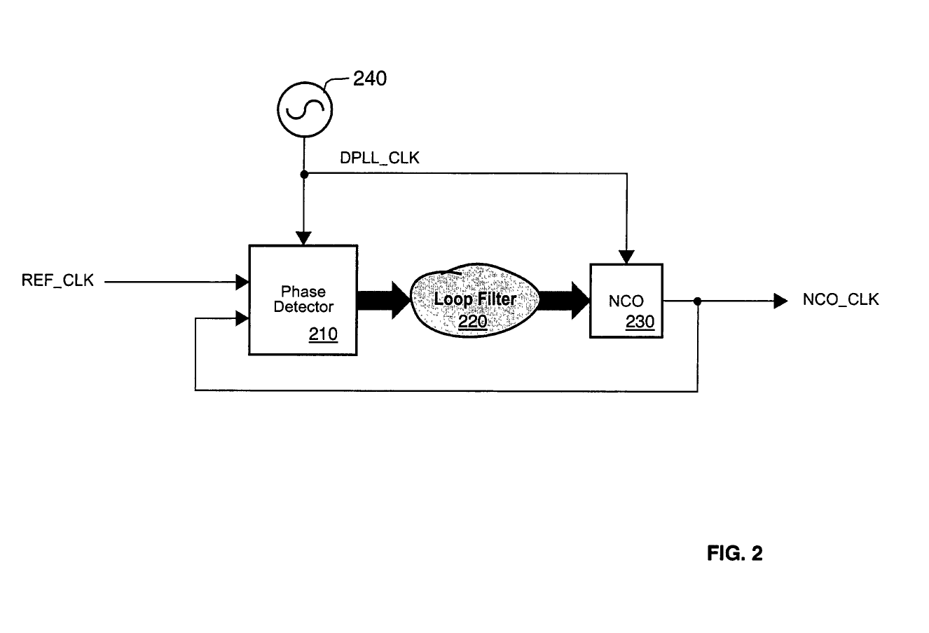

FIG. 2 is a block diagram that illustrates a DPLL 200 according to an embodiment of the present invention. According to an embodiment of the clocking system 100, the DPLL 200 may be implemented as the DPLL 110 shown in FIG. 1. The DPLL 200 includes a phase detector 210, loop filter 220, and a NCO 230. The phase and frequency of the DPLL 200 locks to the incoming reference clock signal (REF_CLK) by adjusting the output frequency of the NCO 230. The DPLL 200 uses a local, free-running oscillator 240 to provide the DPLL_CLK which it uses to quantize the phase error at the phase detector 210. According to an embodiment of the DPLL 200, the oscillator 240 can be either stratum 2 or lower accuracy. The DPLL 200 also uses the DPLL_CLK to clock the NCO 230 and generate the NCO_CLK. According to one embodiment, the DPLL_CLK is set to as high a frequency as practical in order to reduce the quantization error in the phase detector 210 and to reduce the jitter amplitude of the output of the NCO 230.

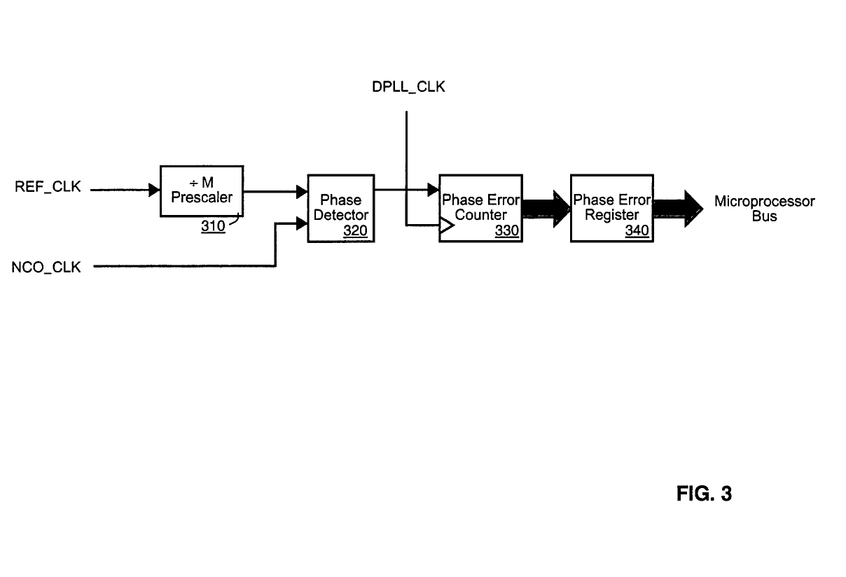

FIG. 3 is a block diagram that illustrates a phase detector 300 according to an embodiment of the present invention. The phase detector 300 may be used to implement the phase detector 210 shown in FIG. 2. The phase detector 300 includes an input prescaler 310, a phase detector unit 320, a phase error counter 330, and a phase error register 340. The phase detector 300 compares the phase of the incoming REF_CLK to the phase of the NCO feedback clock (NCO_CLK). The input REF_CLK is divided down to equal the frequency of NCO_CLK. The phase error is sampled by DPLL_CLK. According to one embodiment, this generates a 14-bit word that quantizes the phase error between REF_CLK and NCO_CLK. This phase error sample is latched to be read.

The input prescaler 310 prescales the REF_CLK such that the phase error detector 320 compares two signals that are equal in frequency. REF_CLK is divided down to equal the NCO_CLK frequency. According to one embodiment, REF_CLK is an integer multiple of NCO_CLK. The value M, is used to describe how the REF_CLK is to be divided down. According to one embodiment of the present invention, M equals the frequency of the REF_CLK divided by the frequency of NCO_CLK. The phase detector unit 320 generates an output pulse width that is equal to the phase difference between the rising edge of REF_CLK and the rising edge of the NCO_CLK. The phase error counter 330 counts the width of the phase error pulse width. The counter resolution is equal to the period of the DPLL clock. The counter resolution is equal to the quantization error which is equal to the inverse of the frequency of the DPLL_CLK. The phase error counter width, k, may be determined by the largest possible phase error count value. This value is a function of the DPLL clock rate and the phase detector reference frequency.

2⁵=(f_{DPLL}_{_{—}}_{CLK})/(f_{PD}_{_{—}}_{REF})

k=log((f_{DPLL}_{_{—}}_{CLK})/(f_{PD}_{_{—}}_{REF})/log(2))→rounded up to the next integer

The phase error register 340 stores the most recent phase error count for the loop filter 220 (shown in FIG. 2) to read. A new phase error count is loaded from the phase error counter 330 into the phase error register 340 each cycle of the NCO output clock signal. The width of this register may be equal to the width of the phase error counter 330.

The loop filter 220 (shown in FIG. 2) may be implemented in software. According to one embodiment, software reads the phase error counts and calculates a frequency estimate for the incoming REF_CLK. A phase increment value is chosen to either increase or decrease the frequency of the NCO to match the frequency of the incoming reference. The loop filter 220 performs the following functions: frequency estimation, proportional integral filtering, phase buildout, holdover, and freerun.

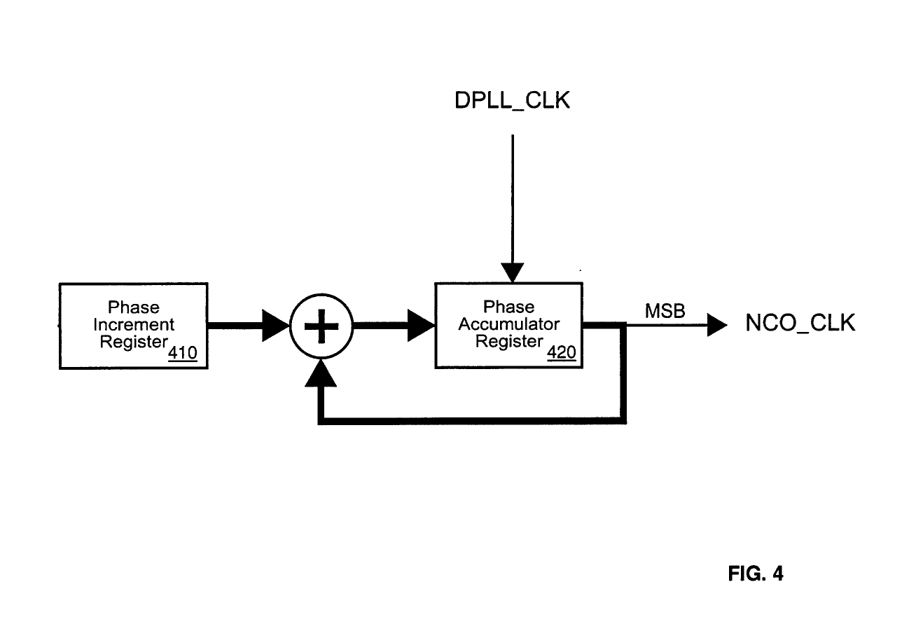

FIG. 4 is a block diagram of an NCO 400 according to an embodiment of the present invention. The NCO 400 may be used to implement the NCO 230 shown in FIG. 2. The NCO 400 includes a phase increment register 410, and a phase accumulator register 420. The phase accumulator register 420 is clocked with the DPLL clock, and the phase increment value is added to the phase accumulator register 420 each DPLL clock cycle. The phase increment value sets the rate at which the NCO 400 wraps around. The most significant bit of the phase accumulator register 420 is used as the NCO output clock.

According to an embodiment of the NCO 400, the behavior of the NCO may be characterized by the following equation.

f_{NCO}_{_{—}}_{CLK}=f_{DPLL}_{_{—}}_{CLK}*(phase increment/2ⁿ),

where n is equal to the phase accumulator width.

The NCO output clock frequency increases linearly with increasing phase increment values for a given DPLL clock frequency. The minimum NCO output clock frequency is zero when the phase increment is set to zero. The maximum NCO output clock frequency is:

maximum f_{NCO}_{_{—}}_{CLK}=f_{DPLL}_{_{—}}_{CLK}*((2¹−1)/2ⁿ),

where i is the width of the phase increment register, and (2¹−1) is the maximum value that can be written to the phase increment register.

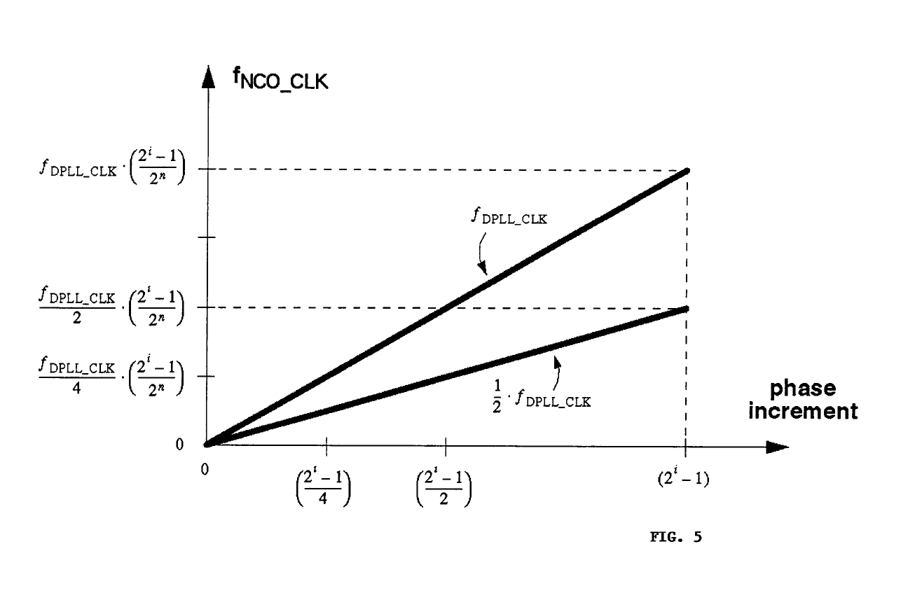

FIG. 5 illustrates the NCO output clock frequency as a function of phase increment for two different DPLL clock frequencies. The NCO output clock is doubled when the DPLL clock is doubled for any given phase increment value. The phase accumulator divides the DPLL clock by the following ratio in order to derive the NCO output clock.

NCO divide ratio=f_{DPLL}_{_{—}}_{CLK}/f_{NCO}_{_{—}}_{CLK}=2ⁿ/phase increment

Whenever this divide ratio is an integer value, the period of the NCO clock will be stable. In other words, the phase accumulator will count the same number of DPLL clock cycles for every NCO clock. However, whenever the divide ratio is a non-integer, the period of the NCO clock will dither between the two integer multiples of the DPLL clock period, since the NCO output clock can only be integer multiples of the DPLL clock. In other words, the NCO output clock period will alternate between two different integer multiples of DPLL clock cycles. For example, assume the NCO divide ratio is a non-integer value with a fractional portion of “0.5”.

NCO divide ratio=k+½,

where k is an integer.

This means that the NCO output clock period will alternate between two integer numbers of DPLL clock cycles of k and (k+1) clock cycles for an average value of (k+½) DPLL clock cycles for every NCO clock cycle.

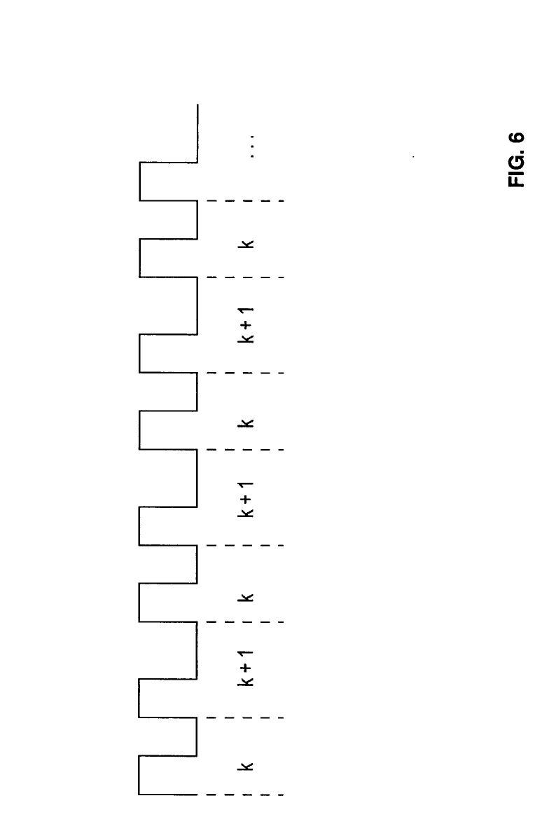

FIG. 6 illustrates NCO output clock period dithering according to an embodiment of the present invention. The dithering of the NCO output clock period will look like instantaneous phase movements of the NCO clock edge equal to one period of the DPLL clock, i.e. jitter. The frequency of this jitter is related to the fractional portion of the NCO divide ratio. The jitter is undesirable and must be filtered before the clock can be used as a system reference clock. According to an embodiment of the present invention, an APLL is used to filter the jitter.

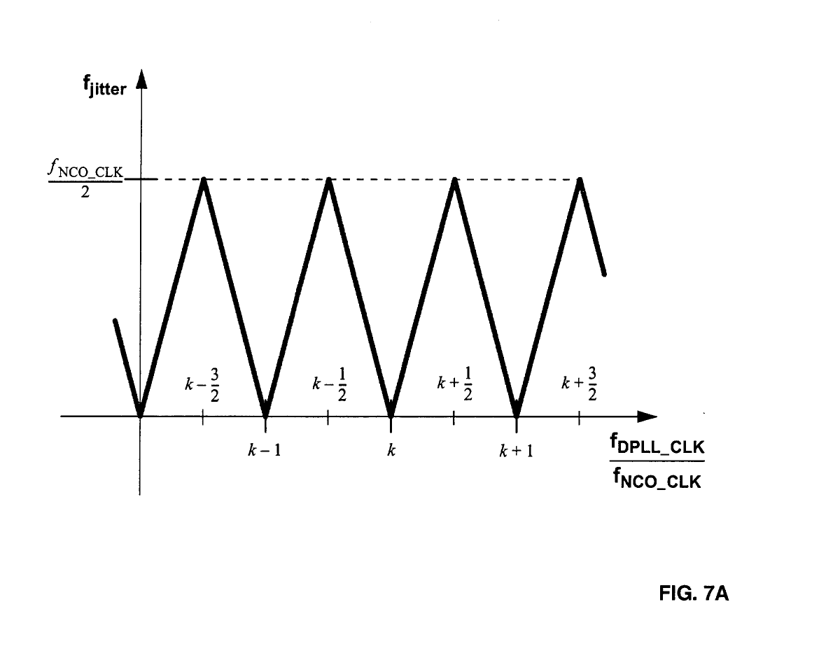

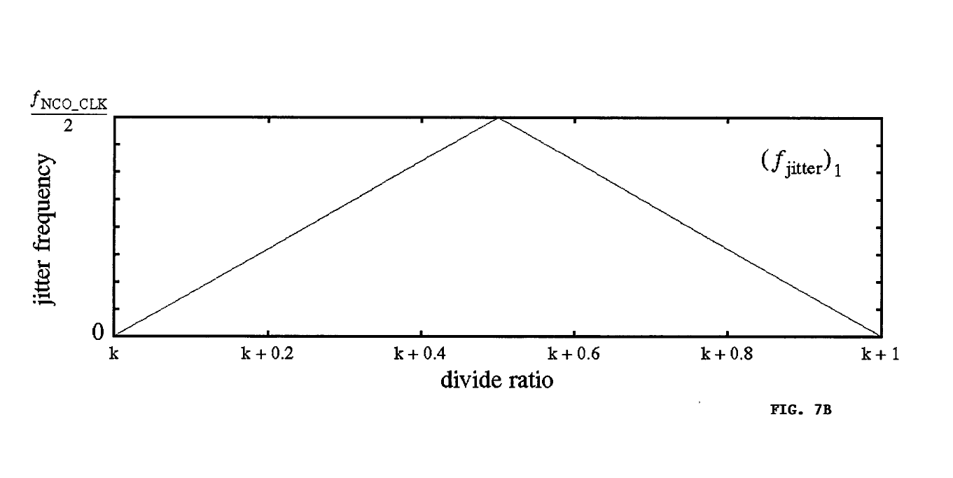

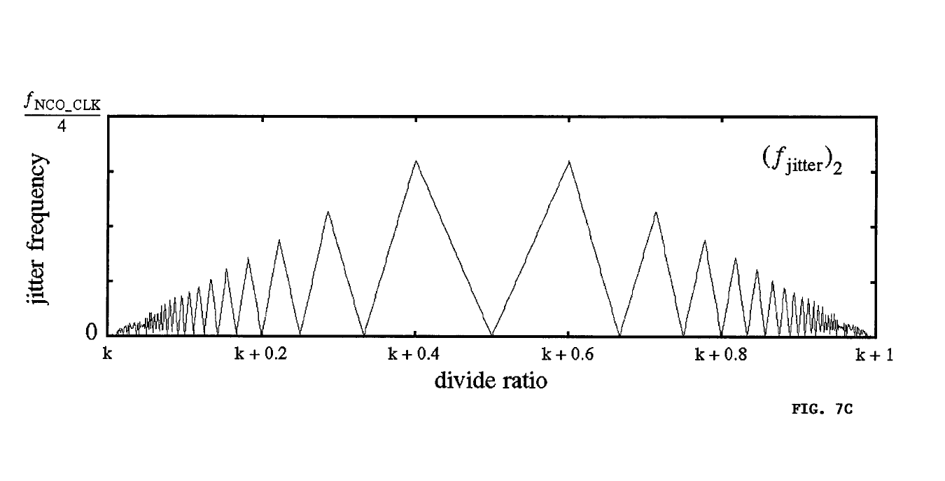

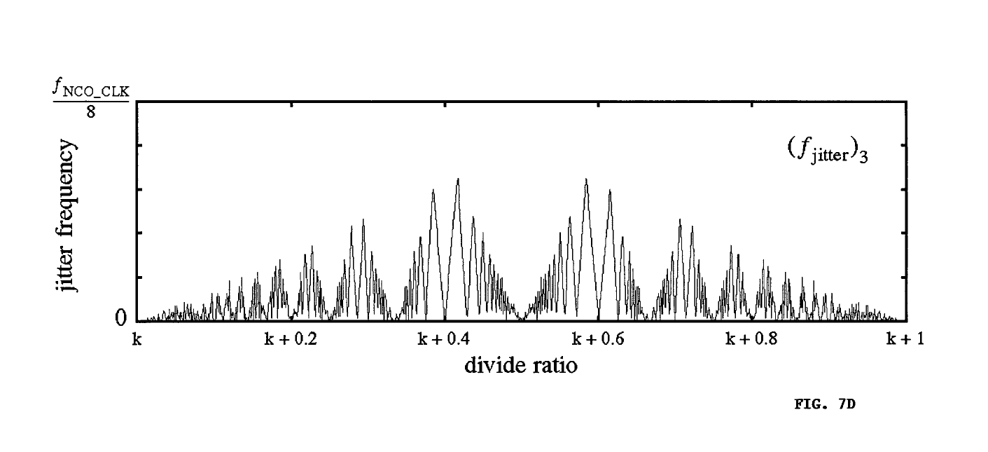

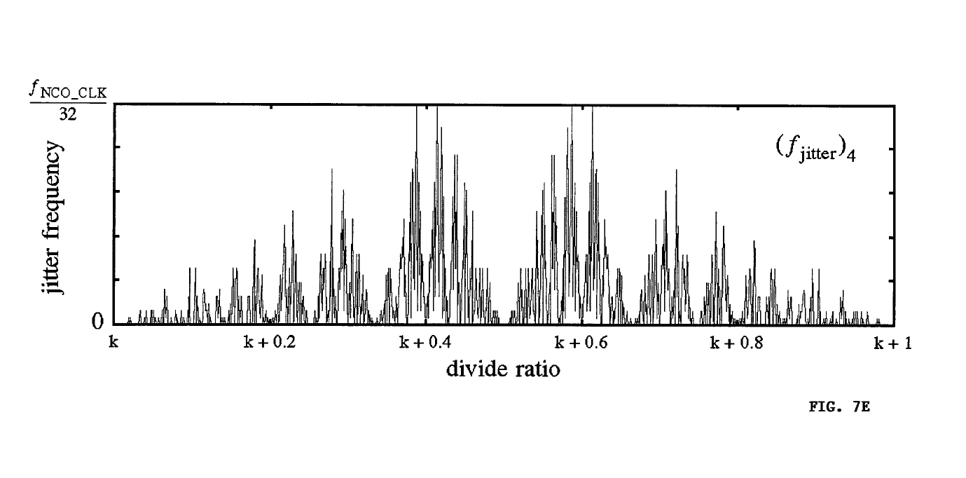

NCO jitter may have certain characteristics. FIG. 7a illustrates NCO jitter frequency as a function of divide ratio. There is zero NCO jitter when the divide ratio is an integer. This is because every cycle of the NCO clock is the same number of DPLL clock cycles wide. The NCO clock period dithers between two integer multiples, k and k+1, every other NCO clock cycle. This results in a maximum NCO jitter frequency of one-half the NCO clock frequency.

As a general rule, we can express the NCO divide ratio in terms of an integer portion and a fractional portion.

NCO divide ratio=k+1/D,

where D is any real number greater than 1.

This relationship may be expanded to further illustrate how the NCO dithers between the two integer multiples of k and k+1.

NCO divide ratio=[(D−1)*(k)+(k+1)]/D]

This relationship can be interpreted as follows. The NCO will approximate the fractional portion of the divide ratio by counting D−1 cycles of k for every 1 cycle of (k+1). This dithering pattern repeats every D cycles of the NCO clock. The number of times the NCO clock dithers between these two values is the lesser of D−1 and 1. Thus, the average frequency of the NCO jitter is the number of times the NCO clock dithers in D cycles of the NCO clock.

fⱼᵢₜₜₑᵣ₌(minimum (D−1,1))/(D*T_{NCO}_{_{—}}_{CLK})=[(minimum (D−1,1)/D]*f_{NCO}_{_{—}}_{CLK}

For example, when D=2, the NCO jitter frequency becomes fⱼᵢₜₜₑᵣ=½*f_{NCO}_{_{—}}_{CLK}.

NCO jitter characteristics may be more intuitive when D is a whole number and less intuitive when D has a fractional portion. When the divide ratio is k+0.32, the following relationships can be seen.

div_{—}ratio=k+1/3.125=(2.125*k+1*(k+1))/3.125.

This illustrates that the NCO will divide by (k+1) once every 3.125 cycles of the NCO clock, and it will divide by k 2.125 times every 3.125 cycles of the NCO clock. However, the NCO can only count in integer multiples of DPLL clock cycles. Thus, the NCO dithers between the following two dithering patterns.

div_{—}ratio1=k+⅓=(2*k+1*(k+1))/3

div_{—}ratio2=k+¼=(3*k+1*(k+1))/4

This will give rise to a second NCO jitter frequency. A second jitter frequency can be determined by applying the above relationships. Thus, P=(7*3+1*4)/8.

This illustrates that the NCO will divide by div_ratio2 once every 8 times. Also, the NCO will divide by div_ratio1 7 out of 8 times. The total pattern length is 25 NCO clock cycles, since the div_ratio2 dithering pattern is 4 NCO clock cycles in length and the div_ratio1 dithering pattern is 3 NCO clock cycles in length.

Total NCO cycles=7*3+1*4=25

Another way of calculating the total pattern length is to multiply the average dithering pattern lengths. Hence:

Total NCO cycles=3.125*8=25

The two jitter frequencies for a divide ratio with a fractional portion of 0.32 are shown below.

fⱼᵢₜₜₑᵣ₁=(1/3.125)*f_{NCO}_{_{—}}_{CLK}

fⱼᵢₜₜₑᵣ₂=(1/25)*f_{NCO}_{_{—}}_{CLK}

The number of pattern cycles, Pᵢ, for a specific jitter component, i, can be expressed in terms of the fractional portion of the number of pattern cycles of the previous jitter component, Pᵢ₋₁.

Pᵢ=Dᵢ, if Dᵢ≧2

Pᵢ=Dᵢ/(Dᵢ−1), if 1<Dᵢ<2

for i≧1 where:

Dᵢ=1/(Pᵢ₋₁−k₁), if i>1

and:

D₁=1/(div_{—}ratio−k₁).

Each NCO jitter period is equal to the length of the jitter pattern in NCO clock cycles times the average NCO output clock period. This may be illustrated by the following relationship where P₁ is the length of the first jitter pattern in NCO clock cycles, (P₂*P₁) is the length of the second jitter pattern in NCO clock cycles, (P₃*P₂*P₁) is the length of the third, and so on. Therefore, the period of each jitter pattern is

$${( {T}_{jitter} )}_{i} = {T}_{NCO\_CLK} \cdot {\prod }_{j = 1}^{i} {P}_{j}$$

For some NCO divide ratios, the number of NCO jitter components are finite, and for others there are an infinite number of components. For example, an NCO divide ratio equal to the square root of 2 produces an infinite series of jitter periods that successively get larger and approach a frequency of zero:

| | |
|---|---|
| k₁ | 1 |
| D₁ | 2.41421. . . |
| P₁ | 2.41421. . . |
| k₂ | 2 |
| D₂ | 2.41421. . . |
| P₂ | 5.82843. . . |
| k₃ | 2 |
| D₃ | 2.41421. . . |
| P₃ | 14.07107. . . |

FIG. 7b-e illustrates the first four NCO jitter frequencies as a function of the NCO divide ratio. The method of this invention will include choosing an NCO operating point such that some of these jitter components are more easily filtered by the APLL.

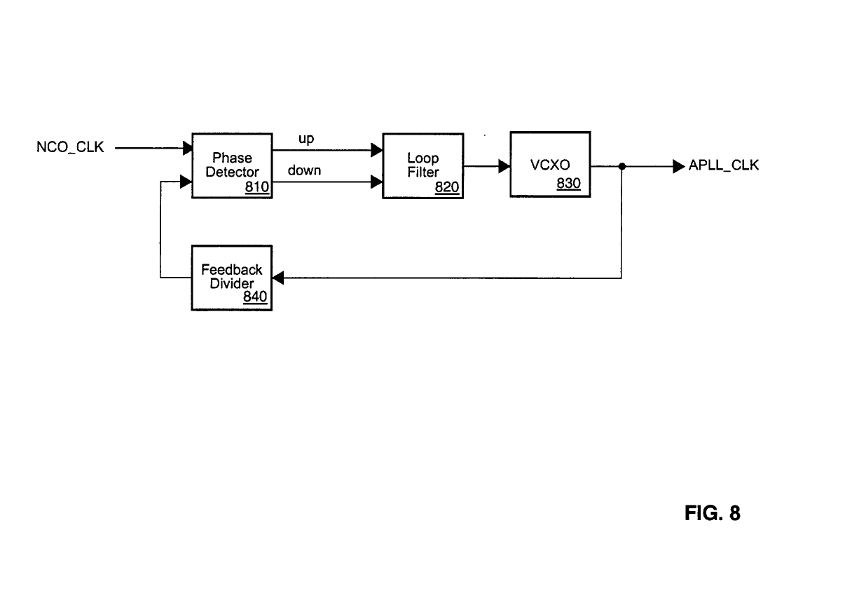

FIG. 8 illustrates an APLL 800 according to an embodiment of the present invention. The APLL 800 may be used to implement APLL 120 shown in FIG. 1. The APLL 800 includes a phase detector 810, loop filter 820, voltage controlled oscillator (VCXO) 830, and feedback divider 840. The phase detector 810 compares the phase of the incoming NCO output clock to the phase of the VCXO 830 feedback signal. The VCXO clock is divided down to equal the frequency of NCO_CLK. The phase detector 810 generates up/down pulses to increase or decrease the frequency of the VCXO 830. The loop filter 820 functions as an integrator to provide an average voltage to the VCXO 830 based on the width and number of up/down pluses. The components in the loop filter 820 sets the loop bandwidth. The VCXO 830 has a center frequency equal to the desired system clock frequency. The NCO output frequency is an integer sub-multiple of the system clock frequency. This eliminates jitter due to modulo counters dithering the period of the feedback signal. The feedback divider 840 divides the system clock by an integer value for comparison to the NCO clock.

According to an embodiment of the clocking system 100 (shown in FIG. 1), the APLL 800 is a type 2, second order PLL. The APLL 800 filters the jitter due to the phase dithering behavior of the NCO from the DPLL 110 (shown in FIG. 1). The noise bandwidth of the APLL 800 is low enough to adequately filter the jitter from the DPLL 110, and high enough that it is not sensitive to phase noise from its internal VCXO 830. The APLL 800 effectively filters out the jitter from the DPLL 110 if its bandwidth is several orders of magnitude lower than the minimum jitter frequency from the DPLL 110. The clock edges from the APLL 800 will lock to the average position of the NCO_CLK edges. Specifically the clock edge position of the APLL 800 will be relative to the fraction portion of the phase accumulator divide ratio. FIG. 9 illustrates the position of the clock edge of the APLL 800 when the bandwidth of the APLL 800 is much less than the jitter frequency of the DPLL 110.

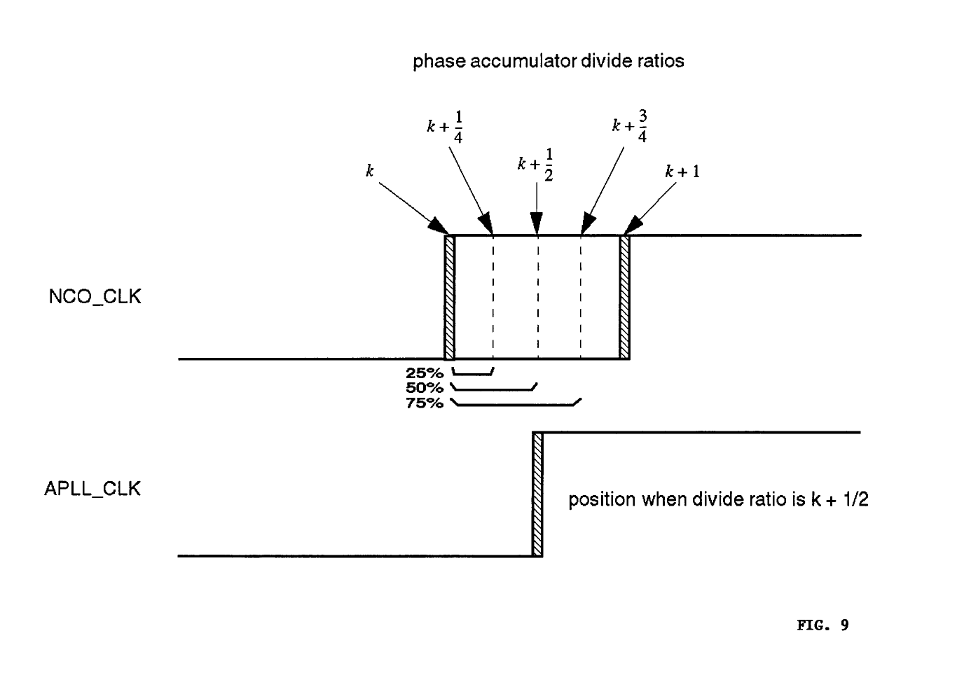

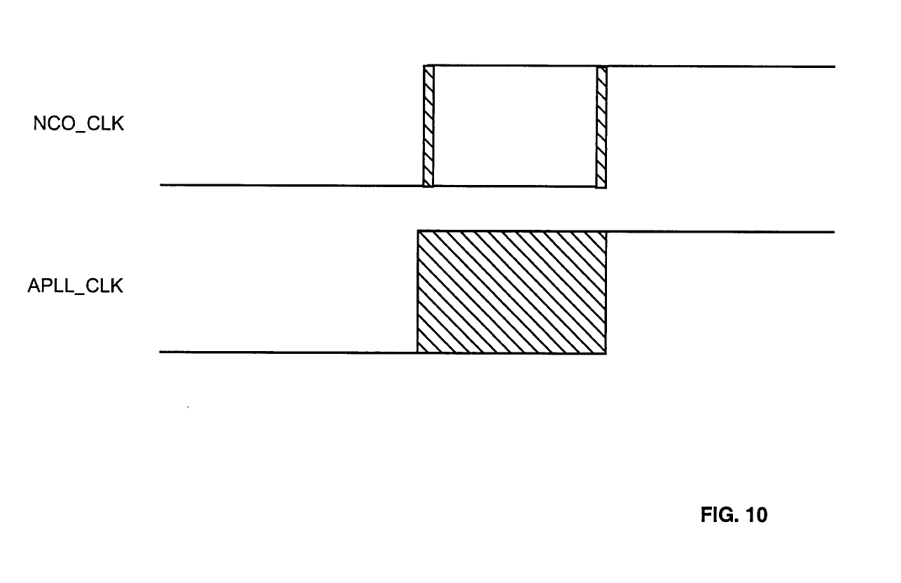

At the other extreme, the APLL 800 tracks the jitter from the DPLL 110, if the bandwidth of the APLL 800 was several orders of magnitude higher than the jitter frequency of the DPLL 110. The APLL_CLK edges would jitter between the two discrete edge locations of the NCO output clock. FIG. 10 illustrates the position of the clock edge of the APLL 800 when the bandwidth of the APLL 800 is much greater than the jitter frequency of the DPLL 110.

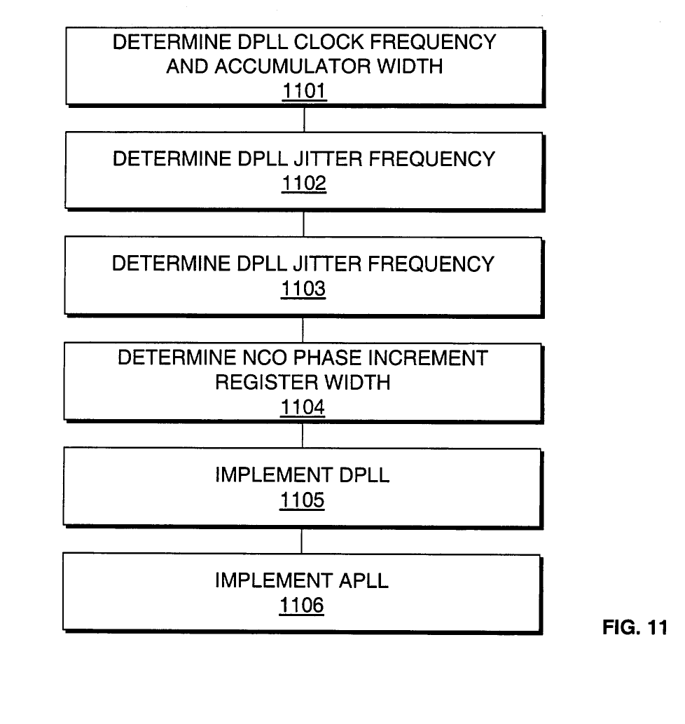

FIG. 11 is a flow chart for designing a clocking system according to an embodiment of the present invention.

At step 1101, a phase detector reference frequency is determined.

At step 1102 a DPLL clock frequency and NCO accumulator width is determined.

At step 1103, the DPLL jitter frequencies are determined.

At step 1104, a NCO phase increment register width is determined.

At step 1105, implement the DPLL.

At step 1106, implement the APLL.

An exemplary clocking system will be designed in order to illustrate the method described above. An example embodiment realizes a stratum 3E clock source for a SONET network element. The requirements for this include synchronizing the clock to a 1.544 MHz input reference, filtering incoming wander according to GR-253 for a stratum 3E clock, and synthesizing a 99.84 MHz system clock that meets jitter and wander specification for the stratum 3E clock.

With reference to step 1101, a phase detector reference frequency is determined. According to an embodiment of the present invention, a common sub-multiple between the input and output frequencies is found in order to synthesize the output frequency from the input frequency. Prime factorization may be used to accomplish this.

f_{REF}_{_{—}}_{CLK}=1544000=2⁶*5³* 193

f_{APPL}_{_{—}}_{CLK}=99840000=2¹²*3*5⁴* 13

Eliminating all prime factors that are not common to both frequencies gives the largest common sub-multiple.

f_{PD}_{_{—}}_{REF}=2⁶*5³=8000 Hz

Thus, 8 kHz may be used as the reference frequency at the phase detector of the DPLL and APLL.

With reference to step 1102, a DPLL clock frequency and the NCO accumulator width is determined. According to an embodiment of the present invention, the DPLL clock frequency is chosen in conjunction with the NCO phase accumulator width such that quantization error in the DPLL phase detector is minimized, jitter amplitude in the NCO output clock is minimized, jitter frequency in the NCO output clock is maximized, and the magnitude of the frequency steps between control values is minimized. On the one hand, the DPLL clock frequency should be as high as possible in order to minimize the DPLL phase detector quantization error and NCO output clock jitter amplitude. On the other hand, the DPLL clock frequency should be as low as possible in order to minimize the magnitude of the frequency steps between NCO control values.

As a starting point, the DPLL clock frequency is set to greater than 100 MHz. This keeps the quantization error to less than 10 ns, and the NCO jitter amplitude under 1 Unit Interval peak-to-peak of the 99.84 MHz system clock. However, the DPLL clock frequency should be as low as possible so that the frequency steps of the NCO are as small as possible. This will improve the accuracy of the holdover mode. We can calculate the incremental change in the NCO output clock frequency for an incremental change in the phase increment as shown below.

Δf_{NCO}_{_{—}}_{CLK}=f_{DPLL}_{_{—}}_{CLK}*(1/2ⁿ),

where n is the width of the phase accumulator.

GR-1244 requires that the initial frequency offset when entering holdover be less than 1 part per billion (ppb). Assuming the NCO output frequency is 8 kHz, this equates to the need for an NCO frequency resolution of 8 microherz.

Δf_{NCO}_{_{—}}_{CLK}=f_{NCO}_{_{—}}_{CLK}*(1 ppb)

=(8 kHz)*(1×10⁻⁹)

=8×10⁻⁶ Hz

Therefore,

(f_{DPLL}_{_{—}}_{CLK})/2ⁿ<8×10⁻⁶ Hz

n>(log(100 MHz/8 μHz)/log(2))=43.5

This means the NCO phase accumulator width, n, must be greater than or equal to 44 bits when the DPLL clock frequency is 100 MHz in order to provide the frequency granularity that is needed for a stratum 3E clock entering holdover. A NCO phase accumulator width of 45 bits may be chosen to provide some margin in the design and to further improve the NCO output frequency granularity. In order to maximize the first order NCO jitter frequency, a non-integer NCO divide ratio with a fractional portion of “0.5” is selected.

NCO divide ratio=f_{DPLL}_{_{—}}_{CLK}/f_{NCO}_{_{—}}_{CLK}=k+½,

where k is an intger.

A DPLL clock frequency is selected that satisfies the above relationship and is greater than 100 MHz. Thus, k is greater than 12500. For this exemplary embodiment, the DPLL clock frequency is selected to be 102.5 MHz. This results in a NCO divide ratio of 12812.5 and which satisfies the requirement choice of having a fractional portion of “0.5”.

With reference to step 1103, DPLL jitter frequencies are determined. According to an embodiment of the present invention, the typical operating range for a stratum 3E clock is +/−4.6 ppm. Therefore the worst-case difference in frequency between the internal oscillator that drives DPLL_CLK the DPLL clock and the external reference is +/−4.6 ppm. Thus, the worst-case difference in frequency between the internal oscillator that drives DPLL_CLK the DPLL clock and the external reference is +/−9.2 ppm. This equates to a maximum divide ratio of:

max divide ratio=((f_{DPLL}_{_{—}}_{CLK(nom)})*(1+4.6 ppm))/((f_{NCO}_{_{—}}_{CLK(nom)})*(1−4.6 ppm))

=12812.6179

Similarly, the minimum divide ratio is:

min divide ratio=((f_{DPLL}_{_{—}}_{CLK(nom)})*(1−4.6 ppm))/((f_{NCO}_{_{—}}_{CLK(nom)})*(1+4.6 ppm))

=12812.3821

Therefore, the first order NCO DPLL jitter frequency ranges from 3056.8 Hz to 4000 Hz:

fⱼᵢₜₜₑᵣ=0.3831*f_{NCO}_{_{—}}_{CLK(min)}=0.3831*8 kHz*(1−4.6 ppm)

=3056.95 Hz

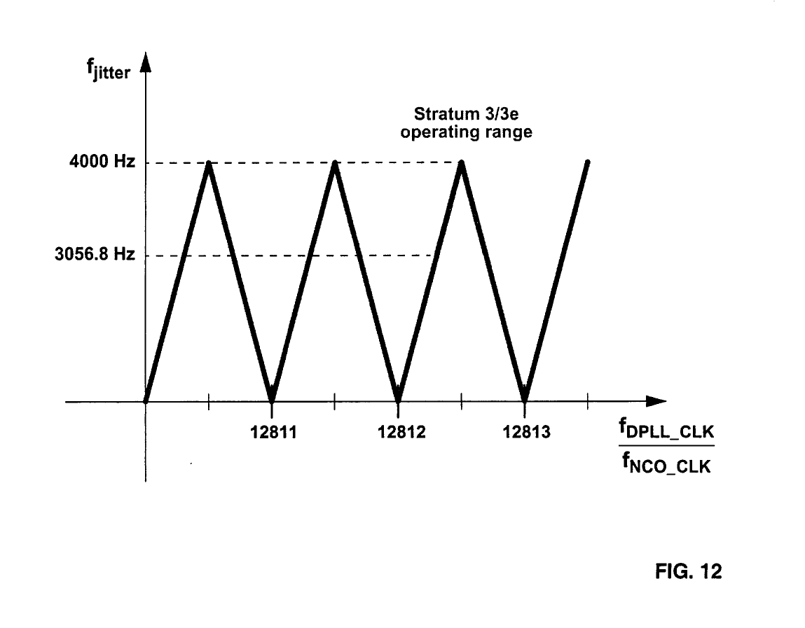

This range of jitter frequencies may be filtered by the APLL. FIG. 12 illustrates this range of NCO DPLL jitter frequencies as a function of the NCO divide ratio.

The example embodiment makes one further optimization in order to maximize the second order NCO jitter frequency. FIG. 7b shows that the second order NCO jitter frequency reaches a maximum at k+0.6. Therefore we will increase the NCO divide ratio to 12812.6 which results in a DPLL clock frequency of 102.5008 MHz. This clock frequency will give rise to first order NCO jitter frequencies in the range of 2256.96 Hz to 4000 Hz, which can still be adequately filtered by the APLL. The second order NCO jitter frequencies can still range down to zero, but the stratum 3E operating range has been optimally centered so that this component is filtered under most operating conditions.

With reference to step 1104, the NCO phase increment register width is determined. According to an embodiment of the present invention, the NCO phase increment register width can be determined once the phase accumulator width and DPLL clock frequency have been determined.

NCO Phase Increment=2ⁿ*(f_{NCO}_{_{—}}_{CLK}/f_{DPLL}_{_{—}}_{CLK})

NCO Phase Increment=2⁴⁵*(8000 Hz/102.5008 MHz)=2746075900.97

k=(log(NCO Phase Increment)/log (2))=31.35

Thus, the NCO phase increment register is selected to be greater than or equal to 32 bits.

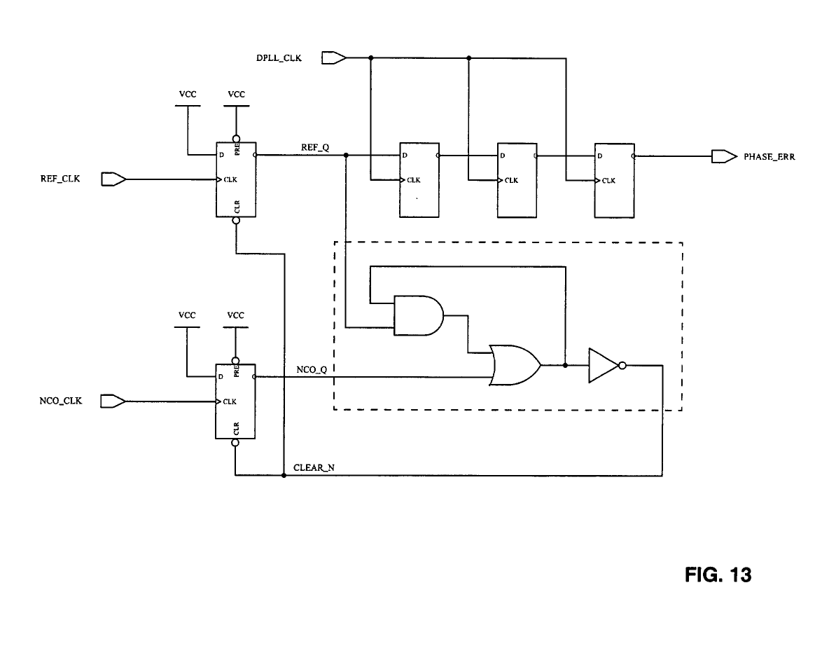

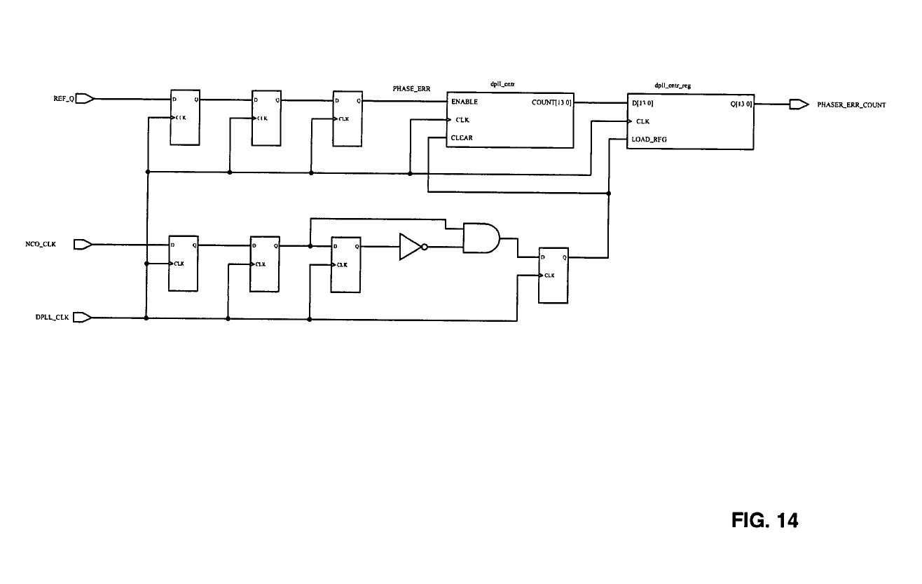

With reference to step 1105, the DPLL is implemented. According to an embodiment of the present invention, the DPLL is implemented with a phase detector, loop filter, and an NCO. The phase detector may be implemented with an input prescaler, phase detector, phase error counter and phase error register. The input prescaler divides the 1.544 MHz clock by 193 to give an 8 kHz signal for comparison to the NCO_CLK. The phase detector may be implemented as shown in FIG. 13. Phase error counter and phase error register may be implemented as shown in FIG. 14. Note that the largest count value is a function of the DPLL clock rate and the phase detector reference frequency. For a DPLL clock rate of 102.5008 MHz and a reference frequency of 8 kHz, the largest possible count value is 12,813.

DPLL Clock Rate/Phase Detector Reference Frequency=102.5008 MHz/8 kHz=12812.6

Thus, the phase error counter must be at least 14 bits wide to accommodate this maximum count.

2^{k}=log (12813)/(log(2)=13.65==>14 bits

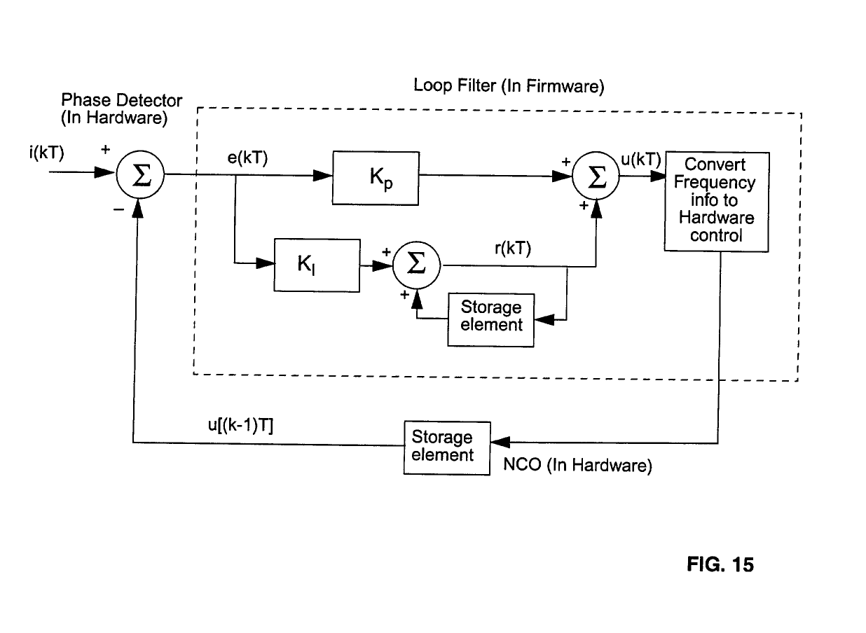

According to an embodiment of the present invention, the DPLL loop filter may be implemented using software. The DPLL loop filter may be represented as shown in FIG. 15. The NCO freerun control value must be set to 2746075901 since the phase accumulator is 45 bits wide, the NCO clock frequency is 102.5 MHz, and the desired NCO output frequency is 8 kHz.

NCO Phase Increment=2⁴⁵*(8000 Hz/102.5008 MHz)=2746075900.97

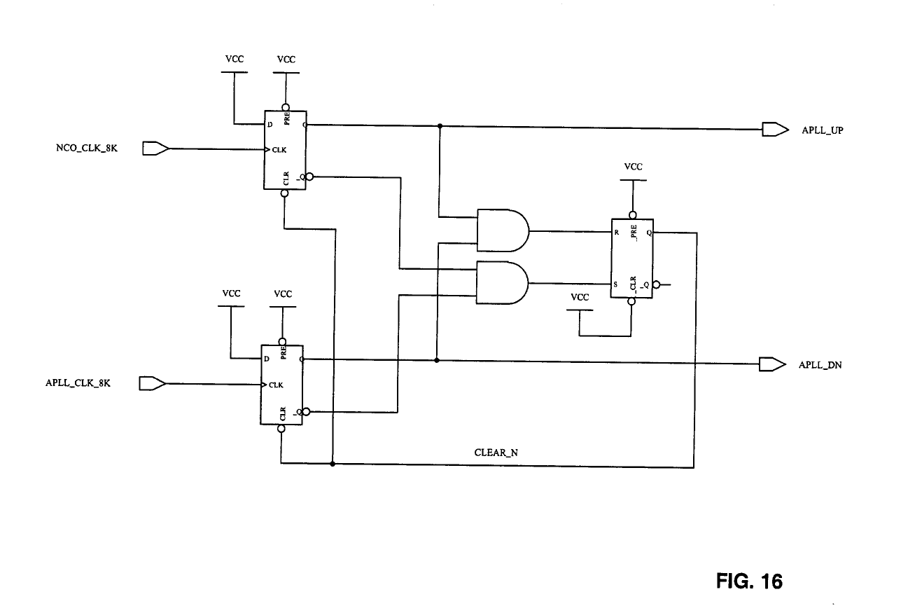

With reference to step 1106, the APLL is implemented. According to an embodiment of the present invention, the APLL may be implemented with a phase detector, loop filter, VCXO, and feedback divider. The phase detector may be implemented as shown in FIG. 16. The VCXO has a center frequency of 99.84 MHz and a pull range of +/−75 ppm. This allows a range for the loop to track the DPLL which will not exceed +/−4.6 ppm from nominal. The feedback divider divides the 99.84 MHz clock by 12,480 to give 8 kHz.

FIG. 9 illustrates a flow chart describing a methods for designing a clock system. Some of the steps illustrated in these figures may be performed in an order other than that which is described. It should be appreciated that not all of the steps described are required to be performed, that additional steps may be added, and that some of the illustrated steps may be substituted with other steps.

In the foregoing specification, the invention has been described with reference to specific exemplary embodiments thereof. It will, however, be evident that various modifications and changes may be made thereto without departing from the broader spirit and scope of the invention. The specification and drawings are, accordingly, to be regarded in an illustrative rather than restrictive sense.

What is claimed is:

1. A clocking system, comprising:
a digital phase-locked loop having a numerically controlled oscillator that generates a clock; and
an analog phase-locked loop, coupled to the digital phase-locked loop, that filters out jitter from the clock to allow the clock to be used as a system clock.

2. The clocking system of claim 1, wherein the digital phase-locked loop further comprises:
a phase detector; and
a loop filter.

3. The clocking system of claim 2, wherein the phase detector comprises:
an input prescaler;
a phase detector unit;
a phase error counter; and
a phase error register.

4. The clocking system of claim 1, wherein the numerically controlled oscillator comprises a phase increment register and a phase accumulator register.

5. The clocking system of claim 4, wherein the phase accumulator generates a word whose most significant bit is used as the clock.

6. The clocking system of claim 1, wherein a frequency of the clock is generated to be related to a frequency of the digital phase-locked loop clock and a phase increment width.

7. The clocking system of claim 2, wherein the loop filter selects a phase increment to match a frequency of the clock with an incoming reference.

8. The clocking system of claim 1, wherein the analog phase-locked loop comprises;
a phase detector unit;
a loop filter;
a voltage controlled oscillator; and
a feedback divider.

9. A method for managing a clocking system, comprising:
determining a phase detector reference frequency;
determining a digital phased-lock loop (DPLL) clock frequency and numerically controlled oscillator (NCO) accumulator width;
determining DPLL NCO jitter frequencies; and
determining a phase increment register width.

10. The method of claim 9, further comprising:
implementing the DPLL; and
implementing the analog phased-lock loop (APLL).

11. The method of claim 9, wherein determining the phase detector reference frequency comprises:
determining common sub-multiples between input and output frequencies; and
eliminating prime factors uncommon to the input and output frequencies.

12. The method of claim 9, wherein determining the DPLL clock frequency and NCO accumulator width comprises selecting a frequency that minimizes a quantization error in a DPLL phase detector, a jitter amplitude in the NCO output clock, and a magnitude of frequency steps between NCO control values.

13. The method of claim 12, further comprising selecting a frequency that maximizes jitter frequency in the NCO output clock.

14. The method of claim 9, wherein determining the NCO phase increment register is based on a NCO accumulator width and a DPLL clock frequency.

15. A method for generating a system clock, comprising:
using a most significant bit from a phase accumulator register of a numerically controlled oscillator (NCO) as a clock.

16. The method of claim 15, further comprising:
managing a frequency of jitter of the clock to allow an analog phased-lock loop (APLL) to filter out the jitter.

17. The method of claim 16, wherein managing the frequency of the jitter comprises increasing the frequency of the jitter.

18. The method of claim 16, wherein managing the frequency of the jitter comprises selecting a reference clock frequency that is a non-integer multiple of a frequency of the clock.
